(19) United States
(12) Patent Application Publication
(10) Pub. No.: US 2026/0005649 A1
(43) Pub. Date: Jan. 1, 2026

(54) OSCILLATOR AND MANUFACTURING METHOD THEREOF, AND ELECTRONIC DEVICE

(71) Applicant: ULTRA SHINING TECHNOLOGY LTD., TAOYUAN (CN)

(72) Inventor: TINGYI CHEN, TAOYUAN (CN)

(21) Appl. No.: 19/319,096

(22) Filed: Sep. 4, 2025

Related U.S. Application Data
(63) Continuation-in-part of application No. PCT/CN2024/090345, filed on Apr. 28, 2024.

(30) Foreign Application Priority Data
Nov. 20, 2023 (CN) 202311543288.2
Oct. 15, 2023 (CN) 202311329213.4

(51) Int. Cl. H03B 5/04; H03B 5/32; H03H 3/02

(52) U.S. Cl. CPC H03B 5/04; H03B 5/32; H03H 3/02

(57) ABSTRACT

An oscillator and a manufacturing method thereof are provided. The oscillator includes a resonator, an oscillation chip, an insulating layer and a first electrode structure. The resonator includes a vibrating element and an airtight packaging structure packaged around the vibrating element. The oscillation chip is arranged on one side of the airtight packaging structure. The insulating layer covers at least one side of the oscillation chip and at least one side of the airtight packaging structure. The insulating layer has a first via hole, and a conductive material is provided in the first via hole. The first electrode structure is arranged on the insulating layer and electrically connected to the oscillation chip through the conductive material inside the first via hole.

### CROSS-REFERENCE TO RELATED APPLICATIONS

This application is a Continuation-in-Part of International Application No. PCT/CN2024/090345, filed on April 28, 2024, which claims priority to Chinese Patent Application No. 202311329213.4, filed on October 15, 2023, and Chinese Patent Application No. 202311543288.2, filed on November 20, 2023, the entire contents of which are incorporated herein by reference.

### TECHNICAL FIELD

The present disclosure relates to the technical field of oscillators, and in particular, to an oscillator and a manufacturing method thereof, and an electronic device.

### BACKGROUND

An oscillator is a product that has been invented/mass-produced for a very long time (over 100 years) and is widely used in various electronic products. Generally, in the prior art, a ceramic base is required for airtight packaging. Specifically, in a manufacturing process, a crystal resonator and an oscillation chip can be packaged together through the ceramic base. Furthermore, during measurement and ion etching, a frequency of the resonator itself is finely adjusted, to adjust a frequency accuracy of the crystal resonator from % to be within +/-10ppm. However, as an important reference source, the oscillator not only has a strict requirement for its high stability (low phase noise, high stability, and high reliability), but also has a strict requirement for its packaging size. Therefore, various oscillator packaging modes have emerged for miniaturization. Meanwhile, due to a requirement for miniaturization, an oscillator composed of a silicon-based resonator has also emerged to compete in this small oscillator market.

### SUMMARY

In view of this, the present invention provides an oscillator and a manufacturing method thereof, and an electronic device.

In a first aspect, the present invention provides an oscillator, which includes a resonator, an oscillation chip, an insulating layer and a first electrode structure. The resonator includes a vibrating element and an airtight packaging structure packaged around the vibrating element.

The oscillation chip is arranged on one side of the airtight packaging structure.

The insulating layer covers at least one side of the oscillation chip and at least one side of the airtight packaging structure. The insulating layer has a first via hole, and a conductive material is provided in the first via hole.

The first electrode structure is arranged on the insulating layer and electrically connected to the oscillation chip through the conductive material inside the first via hole. In a second aspect, the present invention further discloses a manufacturing method of an oscillator, which includes the following steps:

providing an oscillation chip;

providing a resonator, and arranging the resonator on one side of the oscillation chip, where the resonator includes a vibrating element and an airtight packaging structure packaged at a periphery of the vibrating element;

forming an insulating layer with a first via hole on at least one side of the oscillation chip and at least one side of the airtight packaging structure, where a conductive material is provided inside the first via hole; and

forming a first electrode structure on the insulating layer, and electrically connecting the first electrode structure to the oscillation chip through the conductive material inside the first via hole.

In one embodiment, the resonator is a ceramic-packaged crystal resonator, an all-crystal-packaged crystal resonator, or an all-silicon-packaged silicon-based resonator.

In one embodiment, the manufacturing method of the oscillator further includes a step of providing a substrate. The insulating layer includes a substrate portion and a covering portion; the step of forming an insulating layer with a first via hole on at least one side of the oscillation chip and at least one side of the airtight packaging structure includes:

forming the substrate portion on the substrate, and arranging a first surface of the oscillation chip on the substrate portion; and

forming the covering portion on a second surface of the oscillation chip facing away from the first surface, a side surface connected between the first surface and the second surface, and the resonator, and forming the first via hole and the conductive material inside the first via hole in the covering portion,

where both the substrate portion and the covering portion are formed through a semiconductor deposition process; and

the manufacturing method of the oscillator further includes a step of removing the substrate.

In a third aspect, the present application further provides a manufacturing method of an oscillator, including the following steps:

providing a substrate, and forming a first partial insulating layer on the substrate;

arranging an oscillation chip on each of the plurality of crystal resonators, and

forming a plurality of crystal resonators on the first partial insulating layer;

arranging, on each oscillation chip, a plurality of connection ends electrically connected to the oscillation chip, where the connection ends include a first connection end and a second connection end; forming a second partial insulating layer that covers the plurality of crystal resonators and the oscillation chips, where the second partial insulating layer is connected to the first partial insulating layer into a whole;

forming a plurality of second via holes in the second partial insulating layer, where the second via holes are configured to expose a second electrode structure;

forming a first conductive material on the connection ends, on the second partial insulating layer, and inside the second via holes, electrically connecting the second connection ends to the second electrode structure through the first conductive material on the second partial insulating layer and inside the second via holes, and causing the first connection ends to be in contact with and electrically connected to the first conductive material on the first connection ends;

further forming a third partial insulating layer c on the second partial insulating layer and the first conductive material;

forming a plurality of first via holes on the third partial insulating layer, where the plurality of first via holes are configured to expose the first conductive material on the first connection ends;

forming a plurality of first electrode structures on the third partial insulating layer, forming a second conductive material inside the first via holes, and electrically connecting each first electrode structure to the oscillation chips through the second conductive material inside the first via holes;

removing the substrate to obtain a plurality of temperature compensated crystal oscillator main bodies that are connected into a whole; and

cutting the plurality of temperature compensated crystal oscillator main bodies that are connected into a whole, to obtain a plurality of independent temperature compensated crystal oscillator main bodies.

An embodiment of the present invention further provides an electronic device, which includes a circuit board. The oscillator in any one of the above embodiments or obtained by the manufacturing method in any one of the above embodiments is arranged on the circuit board.

The present invention provides an oscillator and a manufacturing method thereof, and an electronic device. The oscillation chip is directly arranged on one side of the packaging structure of the resonator that has been packaged, and the resonator and the oscillation chip are sealed and protected by the insulating layer, without arranging a carrying base body and its cavity for packaging the resonator and the oscillation chip, which avoids the problem of difficulty in reducing the size of the oscillator due to the carrying base body and its cavity, and can achieve minimized packaging of the oscillator. Moreover, since the insulating layer covers the oscillation chip, the oscillation chip is not exposed to the outside, which can better protect the oscillation chip. In addition, the first electrode structure is arranged on the insulating layer, which can cope with the stress generated by placing the oscillator to the client application end on the circuit board, and has a buffering effect, thereby improving the reliability of the oscillator and the reliability of the circuit board with the oscillator. Specifically, the resonator is the all-silicon-packaged silicon-based resonator, which has a smaller size, so that the finally obtained oscillator has a smaller size. In addition, the structural position design of the insulating layer also improves the airtightness of the oscillator.

### BRIEF DESCRIPTION OF THE DRAWINGS

In order to facilitate understanding the present invention, the present invention will be described more comprehensively below with reference to related accompanying drawings. Preferred implementations of the present invention are provided in the drawings. However, the present invention can be implemented in many different forms, and are not limited to the implementations described herein. On the contrary, these implementations are provided to make the content disclosed in the present invention understood more thoroughly and comprehensively.

It should be noted that when an element is referred to as being "fixed to" another element, the element can be directly on another component or there can be a centered element. When an element is considered to be "connected" to another element, the element can be directly connected to another element or there may be a centered element. The terms "inner", "outer", "left", "right", and similar expressions used herein are for illustrative purposes only and do not necessarily represent the only implementation.

Unless otherwise defined, all technical and scientific terms used herein have the same meaning as those commonly understood by a person skilled in the art to which the present invention belongs. Terms used in the specification of the present invention herein are merely intended to describe objectives of the specific embodiments, but are not intended to limit the present invention. The term "and/or" used herein includes any and all combinations of one or more related listed items.

FIG. 1 is a schematic diagram of a sectional structure of an oscillator in one prior art.

FIG. 2 is a schematic diagram of a sectional structure of an oscillator in another prior art.

FIG. 3 is a schematic diagram of a sectional structure of an oscillator according to Embodiment I of the present disclosure.

FIG. 4 is a schematic diagram of a top surface of an oscillator according to Embodiment I of the present disclosure.

FIG. 5 is a schematic diagram of a bottom surface of an oscillator according to Embodiment I of the present disclosure.

FIG. 6 is a perspective diagram of an oscillator according to a change embodiment of Embodiment I of the present disclosure.

FIG. 7 is a schematic diagram of a sectional structure of an oscillator according to a change embodiment of Embodiment I of the present disclosure.

Fig. 8 is a schematic diagram of a sectional structure of an oscillator according to Embodiment II of the present disclosure.

FIG. 9 is a schematic diagram of a sectional structure of an oscillator according to Embodiment III of the present disclosure.

FIG. 10 is a flowchart of a manufacturing method of an oscillator according to Embodiment IV of the present disclosure.

FIG. 11 is a schematic block diagram of an electronic device according to Embodiment V of the present disclosure.

FIG. 12 is a schematic diagram of a sectional structure of a temperature compensated crystal oscillator according to Embodiment VI of the present disclosure.

FIG. 13 is a schematic diagram of a top surface of a temperature compensated crystal oscillator according to Embodiment VI of the present disclosure.

FIG. 14 is a schematic diagram of a bottom surface of a temperature compensated crystal oscillator according to Embodiment VI of the present disclosure.

FIG. 15 is a schematic diagram of a sectional structure of a temperature compensated crystal oscillator according to Embodiment VII of the present disclosure.

FIG. 16 is a schematic diagram of a sectional structure of a temperature compensated crystal oscillator according to Embodiment VIII of the present disclosure.

FIG. 17 is a schematic diagram of a bottom surface of a temperature compensated crystal oscillator according to Embodiment VIII of the present disclosure.

FIG. 18 is a flowchart of a manufacturing method of a temperature compensated crystal oscillator according to Embodiment IX of the present disclosure.

FIG. 19 is a schematic diagram of a sectional structure of a temperature compensated crystal oscillator according to Embodiment X of the present disclosure.

FIG. 20 is a schematic diagram of a bottom surface of a temperature compensated crystal oscillator according to Embodiment X of the present disclosure.

FIG. 21(A) to FIG. 21(N) are schematic structural diagrams of steps of a manufacturing method of a temperature compensated crystal oscillator according to Embodiment XI of the present disclosure.

FIG. 22 is a flowchart of a manufacturing method of a temperature compensated crystal oscillator according to Embodiment XI of the present disclosure. FIG. 23 is a schematic block diagram of an electronic device according to Embodiment XII of the present disclosure.

### DETAILED DESCRIPTION OF THE EMBODIMENTS

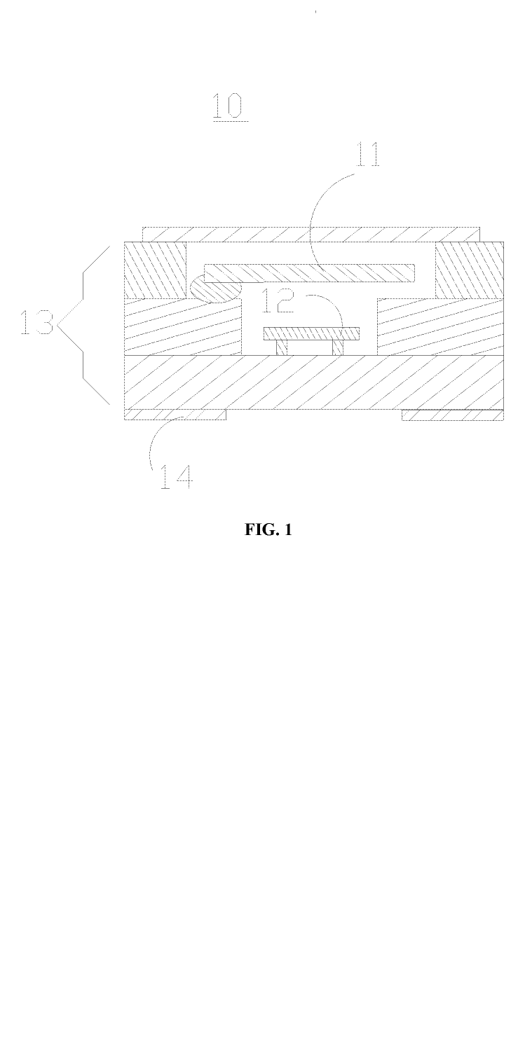

As shown in FIG. 1, in an oscillator 10 in one prior art, a single cavity is formed using a ceramic base 13, and a resonator 11 and an oscillation chip 12 are respectively carried on different layers. Generally, the resonator 11 can be a crystal resonator with a piezoelectric property, so a conductive medium such as a conductive silver paste 15 needs to be used for conduction and fixed on the ceramic base 13. Moreover, since the oscillation chip 12 and the crystal resonator 11 are electrically connected to each other through the ceramic base 13, a pin of the oscillation chip 12 can be measured through an electrode structure 14 (such as a solder pad) at a bottom of the ceramic base 13, thereby ensuring a frequency fine-adjustment process.

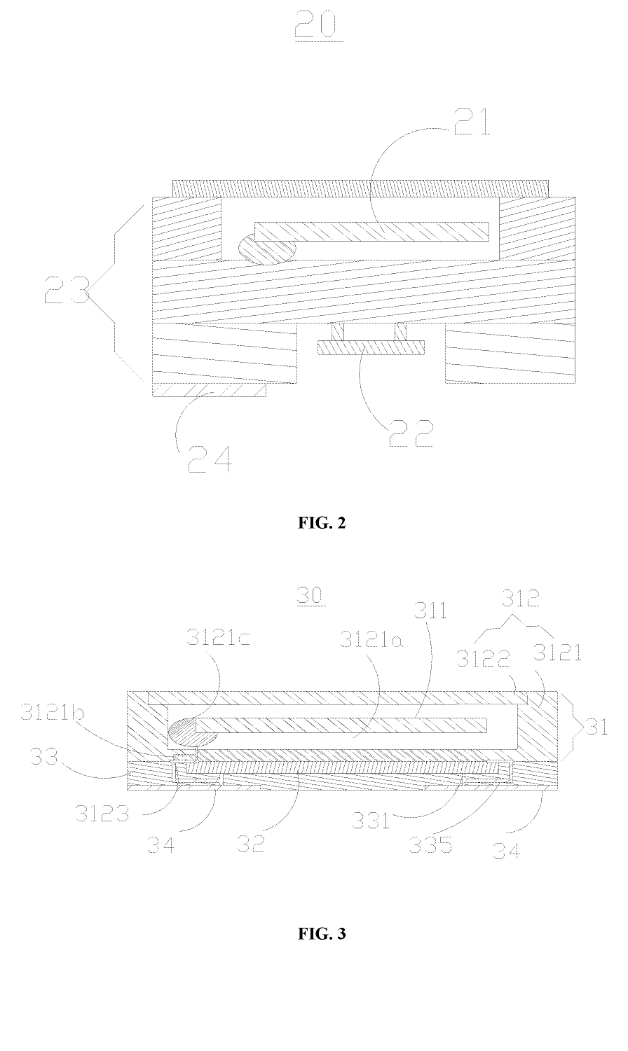

As shown in FIG. 2, in an oscillator 20 in another prior art, a ceramic base 23 can form H-shaped upper and lower cavities to respectively carry an oscillation chip 22 and a resonator 21. The advantage of an H shape is that placement spaces for the oscillation chip 22 and the oscillator 21 can be independent in case of a minimized space.

According to a traditional packaging method shown in FIG. 1 and FIG. 2, no matter how compressed, a carrying base body such as the ceramic base bodies 13, 23 at least need to be provided with bosses for carrying the resonators 11, 21, and pins of the oscillation chips 12, 22 need to be connected through electrode structures 14 at bottoms of the ceramic base bodies 13, 23. However, the inventor has found through a research that there are some drawbacks when the packaging methods shown in FIG. 1 and FIG. 2 are used. Specifically, there is a limitation on miniaturization of sizes of the oscillation chips 12, 22, so that a cavity space needs to be large, thus pressing the ceramic bases 13, 23 and making them narrower and narrower, and the electrode structures 14 and 24 also become relatively narrower. Even some of the most advanced products from top international manufacturers have the technical bottleneck of difficulty in miniaturizing the above oscillators.

It can be understood that due to the use of the above packaging methods, since it is hard to miniaturize the oscillation chips 12, 22, and it is difficult to miniaturize the cavities of the ceramic bases 13, 23, the miniaturization on the entire oscillators 10, 20 is stopped. In addition, in some other prior arts, a silicon-based oscillator also has the technical problem of difficulty in achieving miniaturized packaging.

In view of this, the present disclosure further provides an oscillator structure and a manufacturing method, which can achieve miniaturized packaging and obtain a small-sized oscillator.

An oscillator and a manufacturing method thereof which are provided in the embodiments of the present disclosure will be further explained in detail below with reference to FIG. 3 to FIG. 11.

### Embodiment I

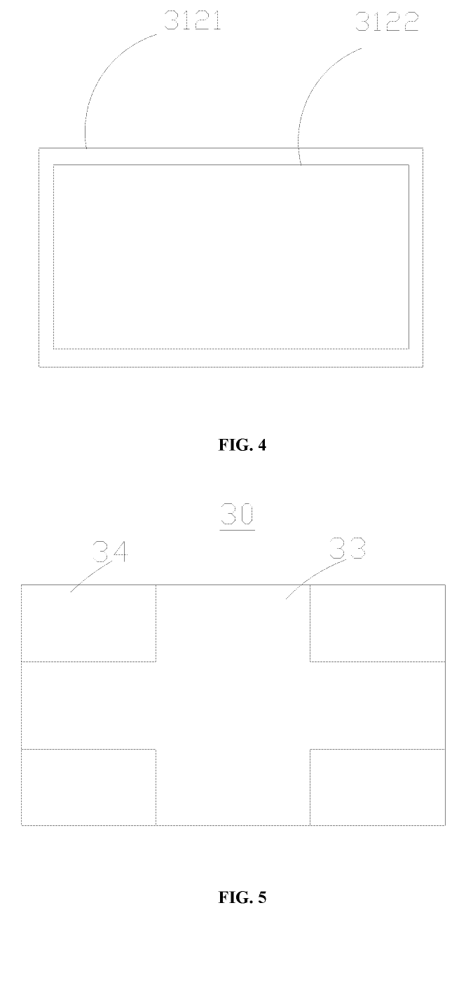

Referring to FIG. 3 to FIG. 5, FIG. 3 is a schematic diagram of a sectional structure of an oscillator 30 according to Embodiment I of the present disclosure. FIG. 4 is a schematic diagram of a top surface of an oscillator 30 according to Embodiment I of the present disclosure. FIG. 5 is a schematic diagram of a bottom surface of an oscillator 30 according to Embodiment I of the present disclosure. The oscillator 30 includes a resonator 31, an oscillation chip 32, an insulating layer 33, and a first electrode structure 34.

The resonator 31 includes a vibrating element 311 and a packaging structure 312 packaged at a periphery of the vibrating element 311. It can be understood that the resonator 31 is a resonant device that has been packaged. In this embodiment, a ceramic-packaged crystal resonator being the resonator 31 is mainly taken as an example for explanation.

The oscillation chip 32 is arranged on one side of an airtight packaging structure 312 and can be electrically connected to the airtight packaging structure 312.

The insulating layer 33 covers at least one side of the oscillation chip 32 and at least one side of the airtight packaging structure 312. The insulating layer 33 has a first via hole 331, and a conductive material is provided in the first via hole 331. The first electrode structure 34 is arranged on the insulating layer 33 and is electrically connected to the oscillation chip 32 through the conductive material inside the first via hole 331. It can be understood that the first electrode structure 34 can be a solder pad structure (such as a solder pad). The insulating layer 33 is made of a resin material. The first electrode structure 34 includes a plurality of first electrodes (i.e. a plurality of solder pads). A quantity of the first via holes 331 can correspond to a quantity of first electrodes, so that the first electrodes can be electrically connected to the conductive materials inside the corresponding first via holes 331. As shown in FIG. 3, in this embodiment, the first electrode structure 34 includes four first electrodes, which are respectively arranged at four corners of a bottom of the oscillator 30.

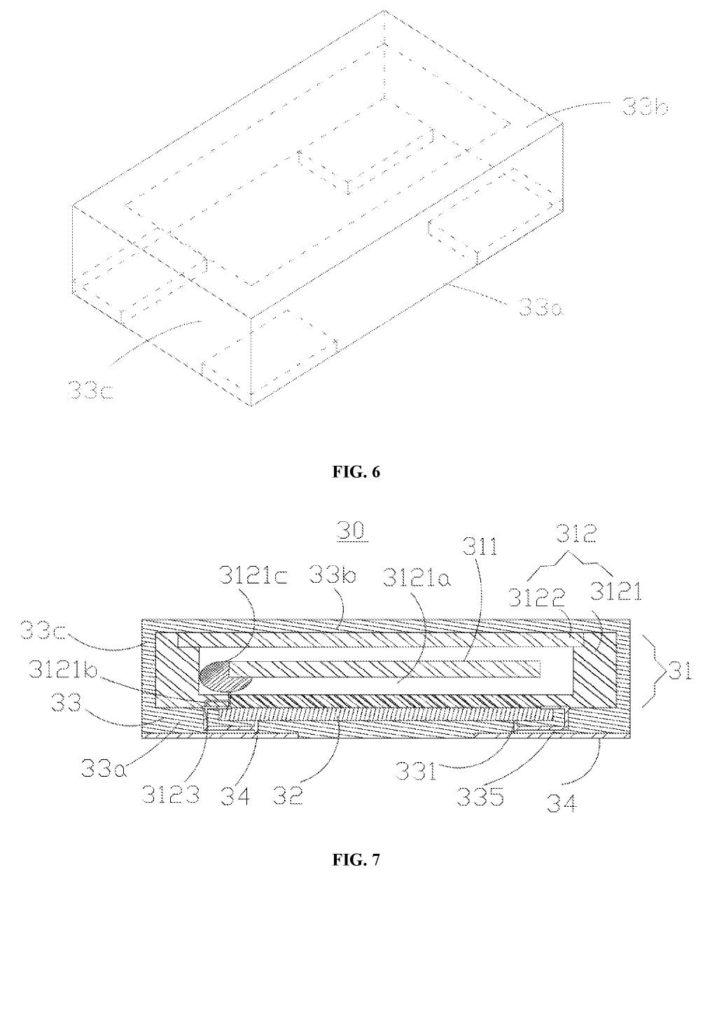

Referring to FIG. 6 and FIG. 7, FIG. 6 is a perspective diagram of an oscillator 30 according to a change embodiment of Embodiment I of the present disclosure. FIG. 7 is a schematic diagram of a sectional structure of an oscillator 30 according to a change embodiment of Embodiment I of the present disclosure. In this change embodiment, the insulating layer 33 covers a peripheral side of the oscillation chip 32 and a peripheral side of the airtight packaging structure 312, so that the oscillation chip 32 and the airtight packaging structure 312 are sealed and protected by the insulating layer 33.

Specifically, as shown in FIG. 6 and FIG. 7, FIG. 6 shows a schematic diagram in which the insulating layer 33 covers the oscillator 30. The insulating layer 33 includes a first portion 33a. The first portion 33a covers one side of the oscillation chip 32 and one side of the airtight packaging structure 312. Namely, the first portion 33a covers a bottom side of the oscillation chip 32 and a bottom side of the airtight packaging structure 312. The insulating layer 33 further includes a second portion 33b. The second portion 33b covers one side of the airtight packaging structure 312 away from the oscillation chip 32. Namely, the second portion 33b covers a top side of the airtight packaging structure 312. The insulating layer 33 further includes a third portion 33c. The third portion 33c is arranged around the peripheral side of the airtight packaging structure 312 and is connected to the first portion 33a and the second portion 33b. Namely, the third portion 33c is arranged on four side surfaces of the airtight packaging structure 312. In this embodiment, the insulating layer 33 completely seals the oscillation chip 32 and the airtight packaging structure 312. The above wrap-around design can provide better protection for the entire structure, thereby improving the reliability of the device. Furthermore, this design also has a technical effect of enhancing buffering on a stress generated by placing the oscillator to a client application end on a circuit board.

Certainly, in other embodiments, the quantity of the first electrodes of the first electrode structure 34 can also be another value, as long as the first electrodes are arranged at the bottom of the oscillator 30. The insulating layer 33 can also cover one or two or more side surfaces of the oscillation chip 32 and the airtight packaging structure 312, which will not be limited in the present disclosure.

In the oscillator 30 provided in this embodiment of the present disclosure, the oscillation chip 32 is directly arranged on one side of the packaging structure 312 of the resonator 31 that has been packaged, and the resonator 31 and the oscillation chip 32 are sealed and protected by the insulating layer 33, without arranging a carrying base body and its cavity for packaging the resonator 31 and the oscillation chip 32, which avoids the problem of difficulty in reducing the size of the oscillator 30 due to the carrying base body and its cavity, and can achieve minimized packaging of the oscillator. Moreover, since the insulating layer 33 covers the oscillation chip 32, the oscillation chip 32 is not exposed to the outside, which can better protect the oscillation chip 32. In addition, the first electrode structure 34 is arranged on the insulating layer 33, which can cope with the stress generated by placing the oscillator 30 to the client application end on the circuit board, and has a buffering effect, thereby improving the reliability of the oscillator 30 and the reliability of the circuit board with the oscillator 30.

Specifically, the airtight packaging structure 312 can include a ceramic base body 3121 with a cavity 3121a, a cover plate 3122 covered at the ceramic base body 3121, and a second electrode structure 3123 arranged on the ceramic base body 3121. A conductor structure 3121b can be arranged inside the ceramic base body 3121. The vibrating element 311 is arranged inside the cavity 3121a and can be electrically connected to the conductor structure 3121b through a conductive adhesive 3121c (such as conductive paste). The second electrode structure 3123 is further electrically connected to the conductor structure 3121b, and the second electrode structure 3123 is further electrically connected to the oscillation chip 32, so that the oscillation chip 32 is electrically connected to the resonator 31. It can be understood that the second electrode structure 3123 can be of a solder pad structure. The second electrode structure 3123 can include a plurality of second electrodes (i.e. a plurality of solder pads). A quantity of the conductor structures 3121b can correspond to a quantity of the second electrodes, so that the second electrodes can be electrically connected to the corresponding conductor structures 3121b. The vibrating element 311 is made of a crystal material.

Further, in this embodiment, the insulating layer 33s further has a second via hole 335. A conductive material is provided inside the second via hole 335. The second electrode structure 3123 is electrically connected to the oscillation chip 32 through the conductive material inside the second via hole 335.

In this embodiment, the insulating layer 33 can be deposited on one side of the oscillation chip 32 and one side of the airtight packaging structure 312 through a first semiconductor deposition process. The first via hole 331 is formed in the insulating layer 33 through a semiconductor etching process. The conductive material is formed in the first via hole 331 through a second semiconductor deposition process. The first electrode structure 34 is formed in the insulating layer 33 through a third semiconductor deposition process. It can be understood that the semiconductor etching process can be achieved by sequentially depositing a material to be etched and a photosensitive etchant, and exposing them with a patterned mask, to achieve patterning of a material layer to be etched.

### Embodiment II

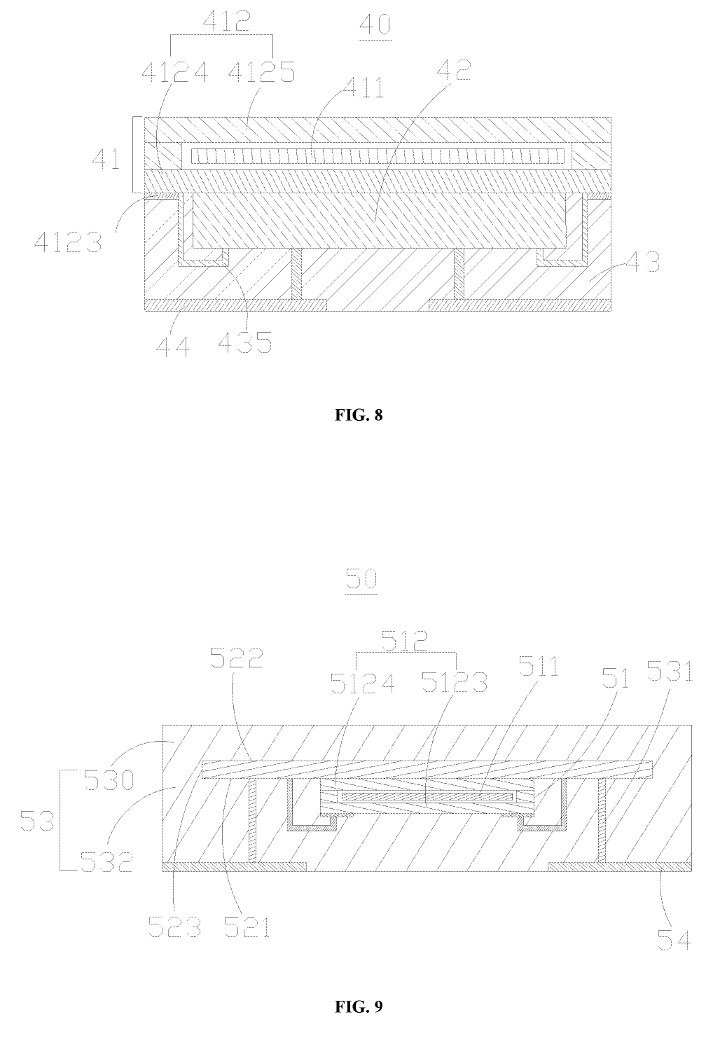

Referring to FIG. 8, FIG. 8 is a sectional view of an oscillator 40 according to Embodiment II of the present disclosure. The oscillator 40 in Embodiment II is basically the same as the oscillator 30 in Embodiment I, which means that the description of the oscillator 30 in Embodiment I can also be applied to the oscillator 40 in Embodiment II. The following will mainly describe differences between the oscillator 40 in Embodiment II and the oscillator 30 in Embodiment I.

In the oscillator 40 of Embodiment II, a first sealing member 4124, a second sealing member 4125, and a vibrating element 411 are all made of crystal materials. Namely, the crystal resonator 41 is an all-crystal-packaged resonator. A packaging structure 412 includes the first sealing member 4124 arranged on one side of the vibrating element 411, the second sealing member 4125 arranged on another side of the vibrating element 411, and a second electrode structure 4123 arranged on the first sealing member 4124. The second electrode structure 4123 is further electrically connected to the oscillation chip 42 through a conductive material inside a second via hole 435.

Specifically, in this embodiment, the oscillation chip 42 is arranged on the first sealing member 4124 and is electrically connected to the second electrode structure 4123, and the insulating layer 33 covers the oscillation chip 42 and the first sealing member 4124.

It can be understood that what is basically the same as Embodiment I is that the oscillation chip 42 is directly arranged on one side of the packaging structure 412 of the resonator 41 that has been packaged, and the resonator 41 and the oscillation chip 42 are sealed and protected by the insulating layer 43, without arranging a carrying base body and its cavity for packaging the resonator 41 and the oscillation chip 42, which avoids the problem of difficulty in reducing the size of the oscillator 40 due to the carrying base body and its cavity, and can achieve minimized packaging of the oscillator. Moreover, since the insulating layer 43 covers the oscillation chip 42, the oscillation chip 42 is not exposed to the outside, which can better protect the oscillation chip 42. In addition, the first electrode structure 44 is arranged on the insulating layer 43, which can cope with the stress generated by placing the oscillator 40 to the client application end on the circuit board, and has a buffering effect, thereby improving the reliability of the oscillator 40 and the reliability of the circuit board with the oscillator 40.

### Embodiment III

Referring to FIG. 9, FIG. 9 is a schematic diagram of a sectional structure of an oscillator 50 according to Embodiment III of the present disclosure. The oscillator 50 in Embodiment III is basically the same as the oscillator 30 in Embodiment I, which means that the description of the oscillator 30 in Embodiment I can also be applied to the oscillator 50 in Embodiment III. The following will mainly describe differences between the oscillator 50 in Embodiment III and the oscillator 30 in Embodiment I.

In the oscillator 50 of Embodiment III, the resonator 51 is an all-silicon-packaged silicon-based resonator, and a coverage position of the insulating layer 53 is different from that in Embodiment I and Embodiment II.

Specifically, in the resonator 51, the airtight packaging structure 512 includes a first a first sealing member 5124 arranged on one side of the vibrating element 511, a second sealing member 5125 arranged on another side of the vibrating element 511, and a second electrode structure 5123 arranged on the first sealing member 5124. The first sealing member 5124, the vibrating element 511, and the second sealing member 5125 all include material silicon, and the second structure 5123 is further electrically connected to the oscillation chip 52 through a conductive material inside a second via hole 535.

The resonator 51 is arranged on a first surface of the oscillation chip 52. The insulating layer 53 covers the resonator 51, the first surface 521 of the oscillation chip 52, a second surface 522 of the oscillation chip 52 facing away from the first surface 521, and a side surface 523 connected between the first surface 521 and the second surface 522.

Specifically, the insulating layer 53 can include a substrate portion 530 and a covering portion 532. The first surface of the oscillation chip 52 is arranged on the substrate portion 530. The covering portion 532 is arranged on the second surface 522 of the oscillation chip 52 facing away from the first surface 521, the side surface 523 connected between the first surface 521 and the second surface 522, and the resonator 51. The substrate portion 530 and the covering portion 532 can be formed in sequence through different semiconductor deposition processes.

It can be understood that in the oscillator 50 of Embodiment III, the insulating layer 53

It can be understood that in the oscillator 50 of Embodiment III, the insulating layer 53 provides coverage protection for both the resonator 51 and the oscillation chip 52, which can not only avoid the problem of difficulty in reducing the size of the oscillator 50 due to a carrying base body and its cavity, but also deal with a stress generated by placing the oscillator 50 on a client application end on a circuit board, and has a buffering effect, thereby further improving the reliability of the oscillator 50 and the reliability of the circuit board with the oscillator 50. In addition, the resonator 51 is the all-silicon-packaged silicon-based resonator, which has a smaller size, so that the finally obtained oscillator 50 has a smaller size. In addition, the structural position design of the insulating layer 53 also improves the airtightness of the oscillator 50.

### Embodiment IV

Referring to FIG. 3 to FIG. 10, FIG. 10 is a flowchart of a manufacturing method of an oscillator according to Embodiment IV of the present disclosure. The manufacturing method includes step S81 to step 584.

Step S81: providing an oscillation chip. As shown in FIG. 3 to FIG. 9, the oscillation chip can be the oscillation chip 32, 42, 52 in any one of Embodiment I to Embodiment III.

S82: providing a resonator, and arranging the resonator on one side of the oscillation chip, where the resonator includes a vibrating element and an airtight packaging structure packaged at a periphery of the vibrating element. Specifically, as shown in FIG. 3 to FIG. 9, the resonator is a ceramic-packaged crystal resonator, an all-crystal-packaged crystal resonator, or an all-silicon-packaged silicon-based resonator. Namely, it can be the resonator 31, 41, 51 in any of Embodiment I to Embodiment III, and will not be elaborated here.

Step S83: forming an insulating layer with a first via hole on at least one side of the oscillation chip and at least one side of the airtight packaging structure, where a conductive material is provided inside the first via hole. It can be understood that the structure of the insulating layer 33, the structure of the first via hole 331, and the conductive material inside the first via hole 331 have been described in detail in Embodiment I, and will not be elaborated here.

Step S84: forming a first electrode structure on the insulating layer, and electrically connecting the first electrode structure to the oscillation chip through the conductive material inside the first via hole. It can be understood that the first electrode structure 34 has been described in detail in Embodiment I, and will not be elaborated here.

Further, as shown in FIG. 9 and FIG. 10, when the resonator 51 is the all-silicon-packaged silicon-based resonator, the manufacturing method of the oscillator further includes step S80 of providing a substrate before step 581. Step S83 can further include step 5831 and step 5832. It can be understood that the substrate can be selected according to an actual need, and includes, but is not limited to, a ceramic base plate, a silicon base plate, and the like.

Step 5831: forming a substrate portion 530 on the substrate, and arranging a first surface 521 of the oscillation chip 52 on the substrate portion 530.

Step S832: forming a covering portion 532 on a second surface of the oscillation chip 52 facing away from the first surface 521, a side surface 523 connected between the first surface 521 and the second surface 522, and the resonator 51, and forming, in the covering portion 532, a first via hole 531 and a conductive material inside the first via hole 531, as well as a second via hole 535 and a conductive material inside the second via hole 535.

The substrate portion 530, the covering portion 532, the conductive material inside the first via hole 531, and the conductive material inside the second via hole 535 can all be formed by a semiconductor deposition process. The first via hole 531 and the second via hole 535 can be both formed by a semiconductor etching process.

The manufacturing method of the oscillator further includes step S85 of removing the substrate after step S84.

### Embodiment V

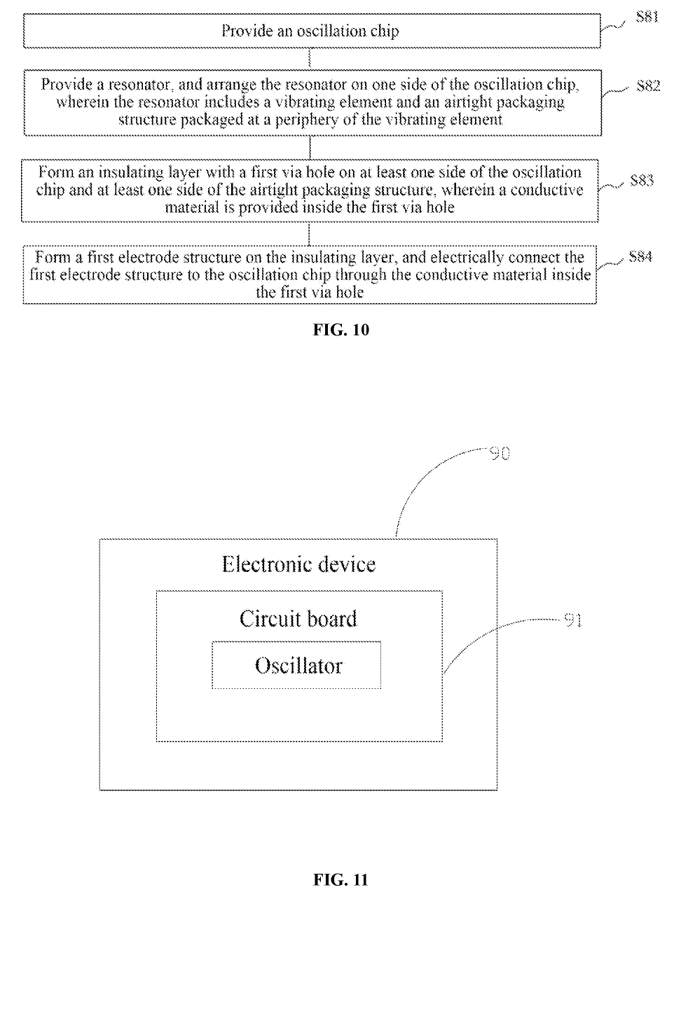

Referring to FIG. 11, FIG. 11 is a schematic block diagram of an electronic device 90 according to Embodiment V of the present disclosure. This embodiment of the present disclosure further provides an electronic device 90. The electronic device 90 can be, but is not limited to, a portable electronic device such as a mobile phone, a tablet, a display, a laptop, and a digital camera. The electronic device 90 can include a circuit board 91. The oscillator 30, 40, or 50 of any embodiment described above is arranged on the circuit board 91.

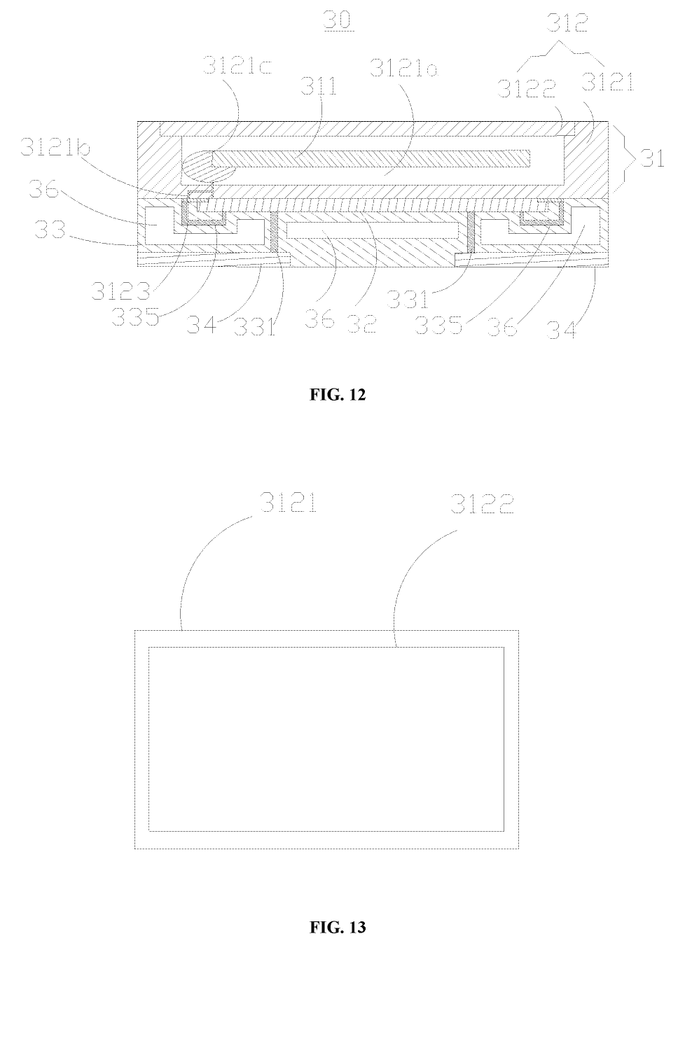

In another aspect, the present disclosure further provides a specific application of the oscillator, such as a temperature compensated crystal oscillator. A specific structure and manufacturing method of the temperature compensated crystal oscillator are both improved based on the structure and manufacturing method of the oscillator, and have differences. For example, in the temperature compensated crystal oscillator, the resonator is a crystal resonator; the oscillation chip is a temperature compensated oscillation chip with a built-in temperature sensor; the insulating layer has a thermal insulation cavity which includes a sealed cavity and/or a semi-closed cavity; and the thermal insulation cavity contains gas or is in vacuum. For detailed description, refer to Embodiment VI to Embodiment X shown in FIG. 12 to FIG. 19.

### Embodiment VI

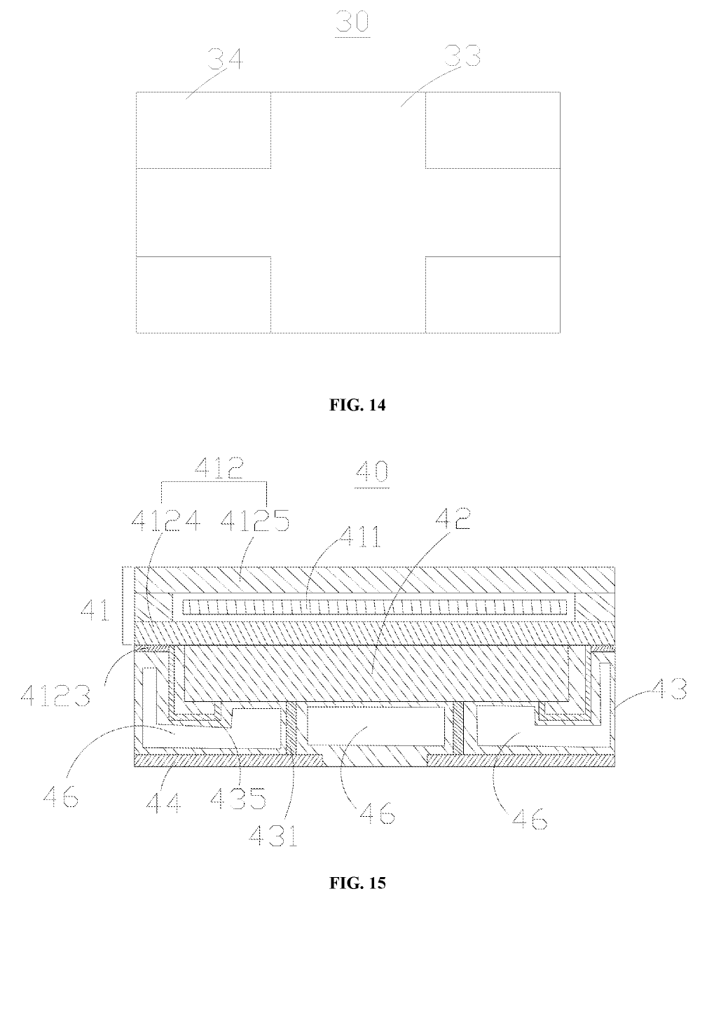

Referring to FIG. 12 to FIG. 14, FIG. 12 is a schematic diagram of a sectional structure of a temperature compensated crystal oscillator 30 according to Embodiment VI of the present disclosure. FIG. 13 is a schematic diagram of a top surface of a temperature compensated crystal oscillator 30 according to Embodiment VI of the present disclosure. FIG. 14 is a schematic diagram of a bottom surface of a temperature compensated crystal oscillator 30 according to Embodiment VI of the present disclosure. The temperature compensated crystal oscillator 30 includes a crystal resonator 31, an oscillation chip 32, an insulating layer 33, and a first electrode structure 34. The oscillation chip 32 is an oscillation chip with a built-in temperature sensor. It can be understood that the temperature sensor can include one or more thermistors.

The crystal resonator 31 includes a vibrating element 311 and a packaging structure 312 packaged at a periphery of the vibrating element 311. It can be understood that the crystal resonator 31 is a crystal resonant device that has been packaged. In this embodiment, a ceramic-packaged crystal resonator being the crystal resonator 31 is mainly taken as an example for explanation.

The temperature compensated oscillation chip 32 is arranged on one side of an airtight packaging structure 312 and can be electrically connected to the airtight packaging structure 312. The insulating layer 33 covers at least one side of the temperature compensated oscillation chip 32 and at least one side of the airtight packaging structure 312. The insulating layer 33 has a first via hole 331, and a conductive material is provided in the first via hole 331. The first electrode structure 34 is arranged on the insulating layer 33 and is electrically connected to the temperature compensated oscillation chip 32 through the conductive material inside the first via hole 331. It can be understood that the first electrode structure 34 can be a solder pad structure (such as a solder pad). The insulating layer 33 is made of a resin material.s The first electrode structure 34 includes a plurality of first electrodes (i.e. a plurality of solder pads). A quantity of the first via holes 331 can correspond to a quantity of first electrodes, so that the first electrodes can be electrically connected to the conductive materials inside the corresponding first via holes 331. As shown in FIG. 12, in this embodiment, the first electrode structure 34 includes four first electrodes, which are respectively arranged at four corners of a bottom of the temperature compensated crystal oscillator 30.

In this embodiment, the insulating layer 33 further has a thermal insulation cavity 36. The thermal insulation cavity 36 is a sealed cavity. The thermal insulation cavity 36 contains gas or is in vacuum, preferably gas, such as but not limited to air. There can be one or more thermal insulation cavities 36, which can be specifically set according to an actual need. In other embodiments, the thermal insulation cavity 36 can also be a semi-closed cavity, which means that the thermal insulation cavity 36 is an open cavity or a hollow region communicated to a periphery of the temperature compensated crystal oscillator 30. For example, an opening communicated to the periphery of the temperature compensated crystal oscillator 30 is provided in at least one side, two opposite sides, or multiple sides of the thermal insulation cavity 36.

In the temperature compensated crystal oscillator 30 provided in this embodiment of the present disclosure, the temperature compensated oscillation chip 32 is directly arranged on one side of the packaging structure 312 of the crystal resonator 31 that has been packaged, and the crystal resonator 31 and the temperature compensated oscillation chip 32 are sealed and protected by the insulating layer 33, without arranging a carrying base body and its cavity for packaging the crystal resonator 31 and the temperature compensated oscillation chip 32, which avoids the problem of difficulty in reducing the size of the temperature compensated crystal oscillator 30 due to the carrying base body and its cavity, and can achieve minimized packaging of the temperature compensated crystal oscillator. Moreover, since the insulating layer 33 covers the temperature compensated oscillation chip 32, the temperature compensated oscillation chip 32 is not exposed to the outside, which can better protect the temperature compensated oscillation chip 32. In addition, the first electrode structure 34 is arranged on the insulating layer 33, which can cope with a stress generated by placing the temperature compensated crystal oscillator 30 to a client application end on a circuit board, and has a buffering effect, thereby improving the reliability of the temperature compensated crystal oscillator 30 and the reliability of the circuit board with the temperature compensated crystal oscillator 30.

Further, by using the thermal insulation cavity 36 in the insulating layer 33, a thermal resistance can be increased to delay thermal impact of an external heat source on the resonator, and a good heat preservation effect can be achieved, making the temperature compensated crystal oscillator 30 more stable in clock oscillation. In addition, the temperature compensated crystal oscillator 30 generally uses a ceramic base and does not need to be directly welded to the circuit board, so there is no need to consider bending strength. This allows the temperature compensated crystal oscillator 30 to be optimized in its size, thickness, and/or material, thus improving the performance of the temperature compensated crystal oscillator 30 and reducing the design difficulty and costs.

Specifically, the airtight packaging structure 312 can include a ceramic base body 3121 with a cavity 3121a, a cover plate 3122 covered at the ceramic base body 3121, and a second electrode structure 3123 arranged on the ceramic base body 3121. A conductor structure 3121b can be arranged inside the ceramic base body 3121. The vibrating element 311 is arranged inside the cavity 3121a and can be electrically connected to the conductor structure 3121b through a conductive adhesive 3121c (such as conductive paste). The second electrode structure 3123 is further electrically connected to the conductor structure 3121b, and the second electrode structure 3123 is further electrically connected to the temperature compensated oscillation chip 32, so that the temperature compensated oscillation chip 32 is electrically connected to the crystal resonator 31. It can be understood that the second electrode structure 3123 can be of a solder pad structure. The second electrode structure 3123 can include a plurality of second electrodes (i.e. a plurality of solder pads). A quantity of the conductor structures 3121b can correspond to a quantity of the second electrodes, so that the second electrodes can be electrically connected to the corresponding conductor structures 3121b. The vibrating element 311 is made of a crystal material.

Further, in this embodiment, the insulating layer 33s further has a second via hole 335. A conductive material is provided inside the second via hole 335. The second electrode structure 3123 can be electrically connected to the temperature compensated oscillation chip 32 through the conductive material inside the second via hole 335. In this embodiment, the insulating layer 33 can be deposited on one side of the temperature compensated oscillation chip 32 and one side of the airtight packaging structure 312 through a first semiconductor deposition process. The first via hole 331 is formed in the insulating layer 33 through a semiconductor etching process. The conductive material is formed in the first via hole 331 through a second semiconductor deposition process. The first electrode structure 34 is formed in the insulating layer 33 through a third semiconductor deposition process. It can be understood that the semiconductor etching process can be achieved by sequentially depositing a material to be etched and a photosensitive etchant, and exposing them with a patterned mask, to achieve patterning of a material layer to be etched.

### Embodiment VII

Referring to FIG. 15, FIG. 15 is a sectional view of a temperature compensated crystal oscillator 40 according to Embodiment II of the present disclosure. The temperature compensated crystal oscillator 40 in Embodiment VII is basically the same as the temperature compensated crystal oscillator 30 in Embodiment VI, which means that the description of the temperature compensated crystal oscillator 30 in Embodiment VI can also be applied to the temperature compensated crystal oscillator 40 in Embodiment VII. The following will mainly describe differences between the temperature compensated crystal oscillator 40 in Embodiment VII and the temperature compensated crystal oscillator 30 in Embodiment VI.

In the temperature compensated crystal oscillator 40 of Embodiment VII, a first sealing member 4124, a second sealing member 4125, and a vibrating element 411 are all made of crystal materials. Namely, the crystal resonator 41 is an all-crystal-packaged crystal resonator. A packaging structure 412 includes the first sealing member 4124 arranged on one side of the vibrating element 411, the second sealing member 4125 arranged on another side of the vibrating element 411, and a second electrode structure 4123 arranged on the first sealing member 4124. The second electrode structure 4123 is further electrically connected to the oscillation chip 42 through a conductive material inside a second via hole 435.

Specifically, in this embodiment, the temperature compensated oscillation chip 42 is arranged on the first sealing member 4124 and is electrically connected to the second electrode structure 4123, and the insulating layer 43 covers the oscillation chip 42 and the first sealing member 4124.

In this embodiment, the insulating layer 43 further has a thermal insulation cavity 46. The thermal insulation cavity 46 is a sealed cavity. The thermal insulation cavity 46 contains gas or is in vacuum, preferably gas, such as but not limited to air. There can be one or more thermal insulation cavities 46, which can be specifically set according to an actual need.

It can be understood that what is basically the same as that in Embodiment VI is that the temperature compensated oscillation chip 42 is directly arranged on one side of the packaging structure 412 of the crystal resonator 41 that has been packaged, and the crystal resonator 41 and the temperature compensated oscillation chip 42 are sealed and protected by the insulating layer 43, without arranging a carrying base body and its cavity for packaging the crystal resonator 41 and the temperature compensated oscillation chip 42, which avoids the problem of difficulty in reducing the size of the temperature compensated crystal oscillator 40 due to the carrying base body and its cavity, and can achieve minimized packaging of the temperature compensated crystal oscillator. Moreover, since the insulating layer 43 covers the temperature compensated oscillation chip 42, the temperature compensated oscillation chip 42 is not exposed to the outside, which can better protect the temperature compensated oscillation chip 42. In addition, the first electrode structure 44 is arranged on the insulating layer 43, which can cope with a stress generated by placing the temperature compensated crystal oscillator 40 to a client application end on a circuit board, and has a buffering effect, thereby improving the reliability of the temperature compensated crystal oscillator 40 and the reliability of the circuit board with the temperature compensated crystal oscillator 40.

Further, by using the thermal insulation cavity 46 in the insulating layer 43, a thermal resistance can be increased to delay thermal impact of an external heat source on the resonator, and a good heat preservation effect can be achieved, making the temperature compensated crystal oscillator 40 more stable in clock oscillation. In addition, the temperature compensated crystal oscillator 40 generally uses a ceramic base and does not need to be directly welded to the circuit board, so there is no need to consider bending strength. This allows the temperature compensated crystal oscillator 40 to be optimized in its size, thickness, and/or material, thus improving the performance of the temperature compensated crystal oscillator 40 and reducing the design difficulty and costs.

### Embodiment VIII

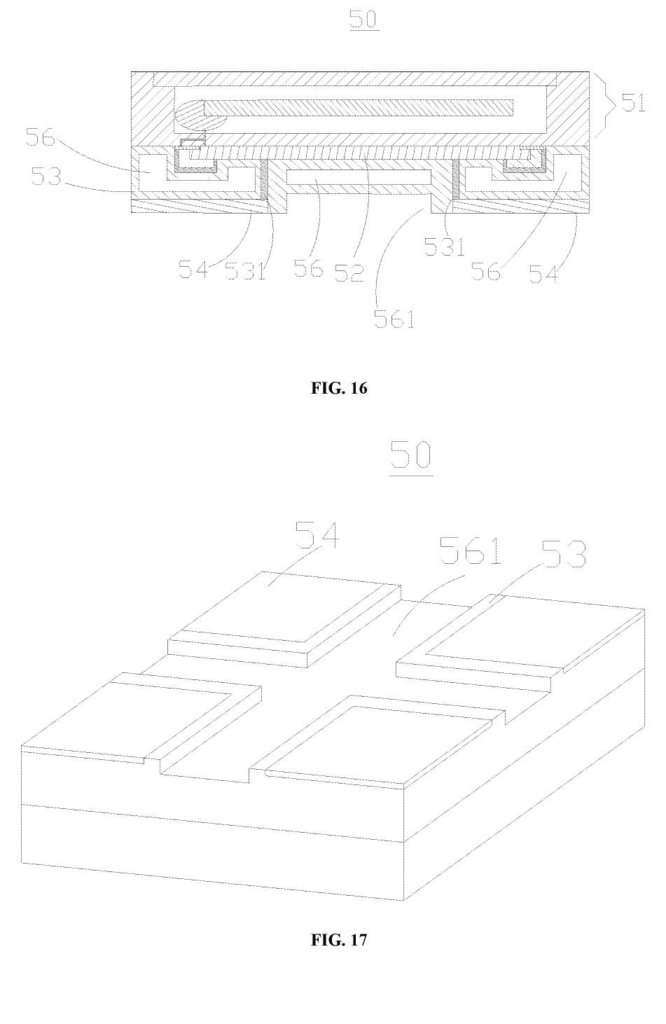

Referring to FIG. 16 and FIG. 17, FIG. 16 is a sectional view of a temperature compensated crystal oscillator 50 according to Embodiment VIII of the present disclosure. FIG. 17 is a schematic diagram of a bottom of a temperature compensated crystal oscillator 50 according to Embodiment VIII of the present disclosure. The temperature compensated crystal oscillator 50 in Embodiment VIII is basically the same as the temperature compensated crystal oscillator 30 in Embodiment VI, which means that the description of the temperature compensated crystal oscillator 30 in Embodiment VI can also be applied to the temperature compensated crystal oscillator 50 in Embodiment VIII. The following will mainly describe differences between the temperature compensated crystal oscillator 50 in Embodiment VIII and the temperature compensated crystal oscillator 30 in Embodiment VI.

In the temperature compensated crystal oscillator 50, the thermal insulation cavity 56 of the insulating layer 53 further includes a semi-closed cavity 561. In this embodiment, the semi-closed cavity 561 is of a groove structure arranged around a periphery of the first electrode structure.

It can be understood that the above semi-closed cavity 561 can better achieve technical effects of thermal insulation and bottom heat dissipation, thereby improving the reliability of the temperature compensated crystal oscillator 50 and the reliability of a circuit board with the temperature compensated crystal oscillator 50.

### Embodiment IX

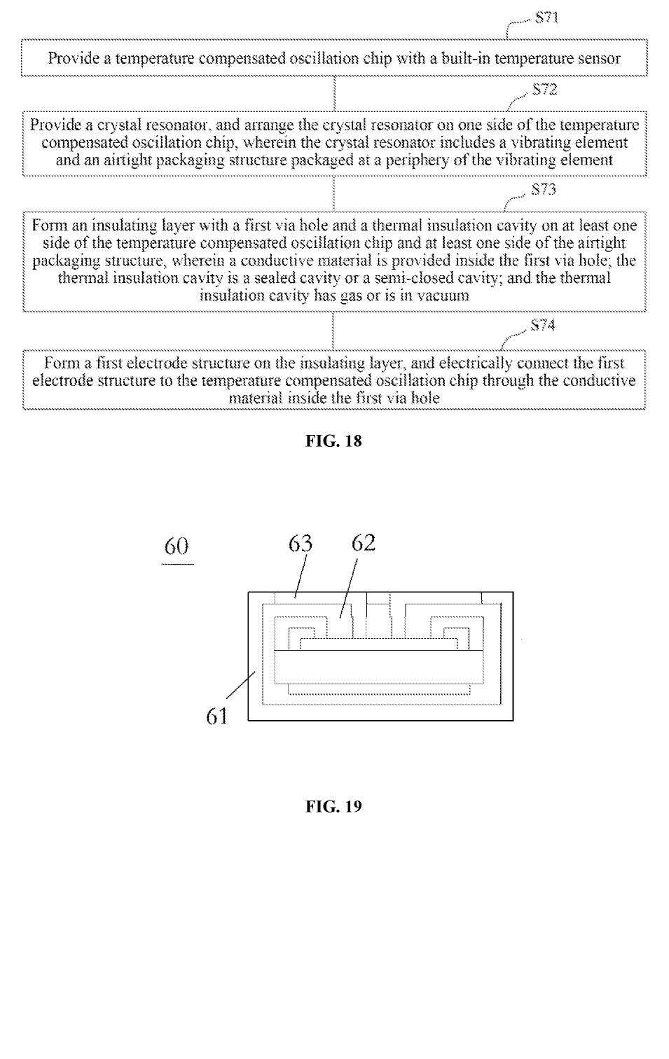

Referring to FIG. 12 to FIG. 18, FIG. 18 is a flowchart of a manufacturing method of a temperature compensated crystal oscillator according to Embodiment IX of the present disclosure. The manufacturing method includes step S71 to step S74.

StepS71: providing an oscillation chip. As shown in FIG. 12 to FIG. 18, the temperature compensated oscillation chip can be the oscillation chip 32, 42, 52 in any one of Embodiment VI to Embodiment VIII.

Step S72: providing a crystal resonator, and arranging the crystal resonator on one side of the temperature compensated oscillation chip, where the crystal resonator includes a vibrating element and an airtight packaging structure packaged at a periphery of the vibrating element. Specifically, as shown in FIG. 12 to FIG. 17, the crystal resonator is a ceramic-packaged crystal resonator, or an all-crystal-packaged crystal resonator. Namely, it can be the crystal resonator 31, 41, 51 in any of Embodiment VI to Embodiment VIII, and will not be elaborated here.

Step S73: forming an insulating layer with a first via hole and a thermal insulation cavity on at least one side of the temperature compensated oscillation chip and at least one side of the airtight packaging structure, where a conductive material is provided inside the first via hole. The thermal insulation cavity includes a sealed cavity and/or a semi-closed cavity, and the thermal insulation cavity has gas or is in vacuum. It can be understood that the structure of the insulating layer 33, 43, 53, the structure of the first via hole 331, 431, 531 and the structure of the thermal insulation cavity 36, 46, 56, and the conductive material inside the first via hole 331, 431, 531 have been described in detail in Embodiment VI, and will not be elaborated here.

Step S74: forming a first electrode structure on the insulating layer, and electrically connecting the first electrode structure to the temperature compensated oscillation chip through the conductive material inside the first via hole. It can be understood that the first electrode structure 34, 44, 54 has been described in detail in Embodiment VI, and will not be elaborated here.

### Embodiment X

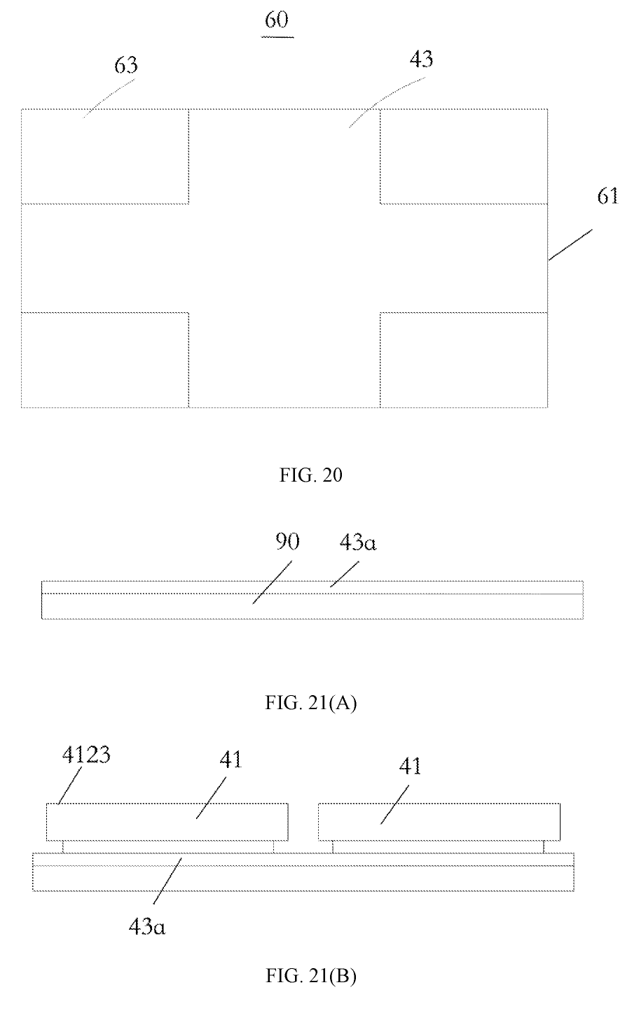

Referring to FIG. 19 and FIG. 20, a temperature compensated crystal oscillator 60 in Embodiment X is basically the same as the temperature compensated crystal oscillator 40 in Embodiment II (as shown in FIG. 8), which means that the description of the temperature compensated crystal oscillator 30 in Embodiment II can also be applied to the temperature compensated crystal oscillator 60 in Embodiment X. The following will mainly describe differences between the temperature compensated crystal oscillator 60 in Embodiment X and the temperature compensated crystal oscillator 30 in Embodiment II.

In this embodiment, a main difference between the temperature compensated crystal oscillator 60 and the temperature compensated crystal oscillator 40 (as shown in FIG. 8) in Embodiment II is as follows: The temperature compensated crystal oscillator 60 further includes a protective structure 61. The protective structure 61 can be made of an insulating material and is wrapped around a periphery of a temperature compensated crystal oscillator main body 62 (namely, which is basically the same as the structure of the temperature compensated crystal oscillator 40 shown in FIG. 8), and only an electrode structure 63 (which is equivalent to the first electrode structure 44 shown in FIG. 8) is exposed through an opening region of the protective structure 61, thereby electrically connecting an oscillation chip 42 inside the temperature compensated crystal oscillator main body 62 to an external device or circuit through the electrode structure 63. Specifically, a thickness of the protective structure 61 can be designed according to actual needs. In this embodiment, the protective structure 61 covers most of a region of the temperature compensated crystal oscillator main body 62, and only exposes the electrode structure 63, thereby ensuring protection for the temperature compensated crystal oscillator main body 62 and improving reliability of the temperature compensated crystal oscillator 60.

### Embodiment XI

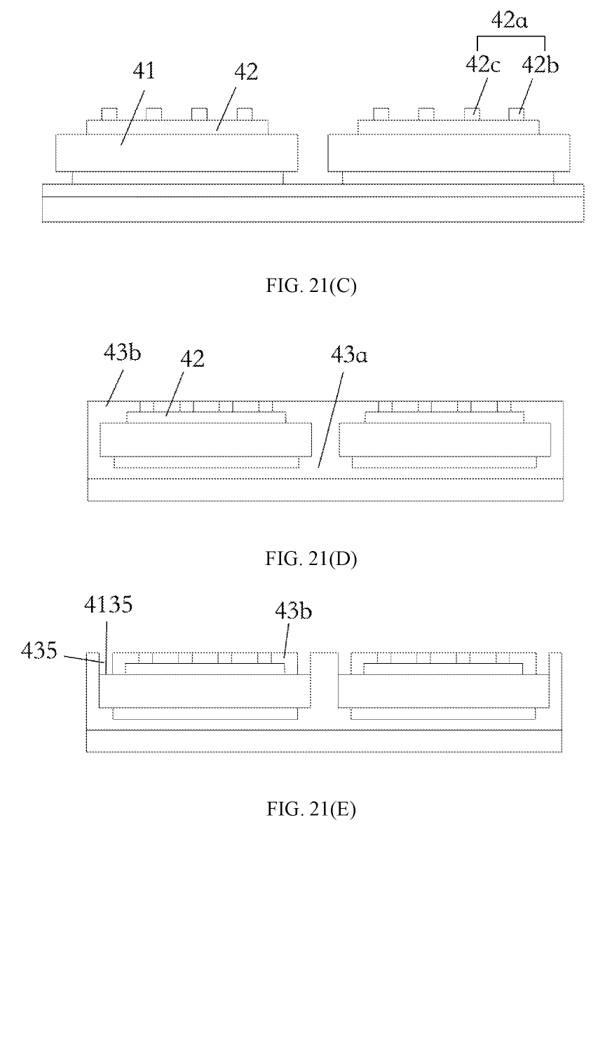

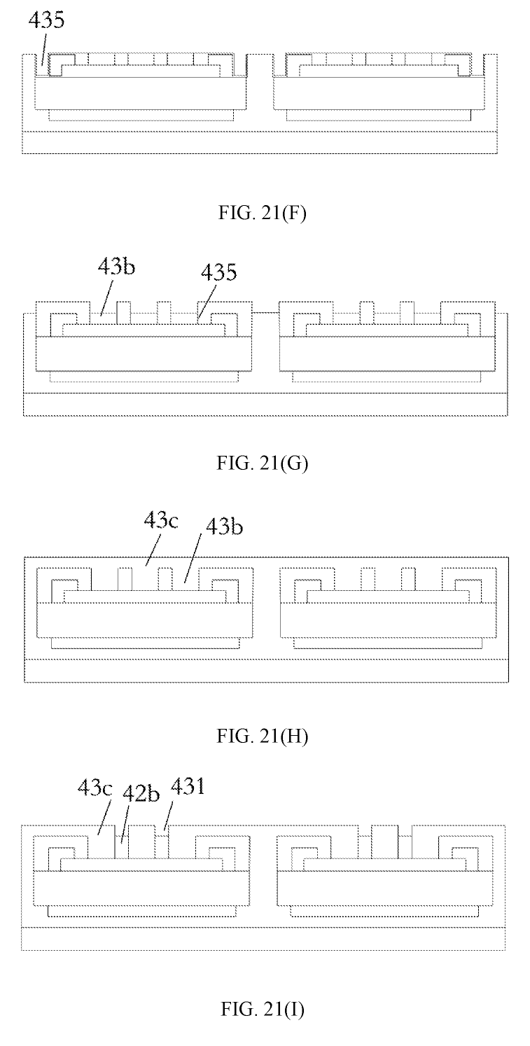

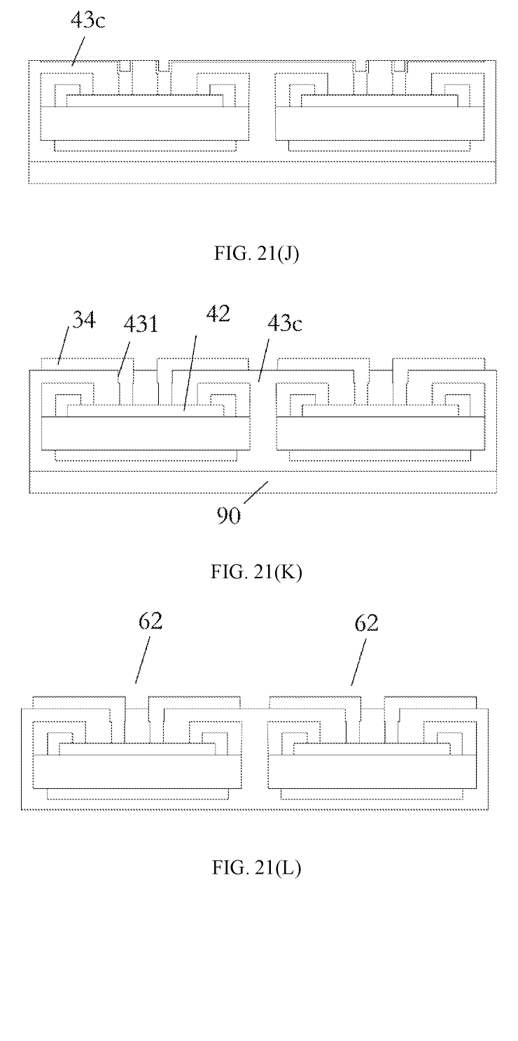

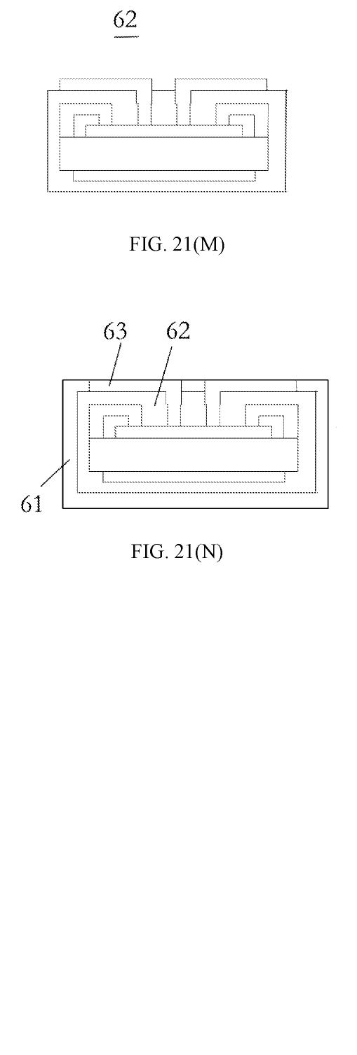

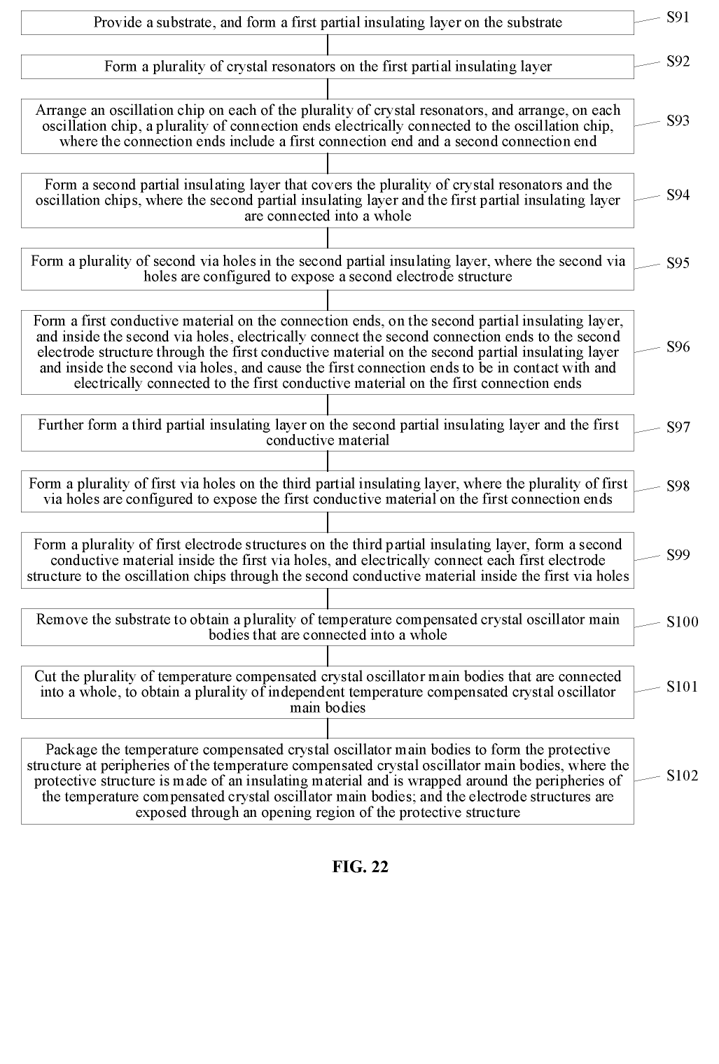

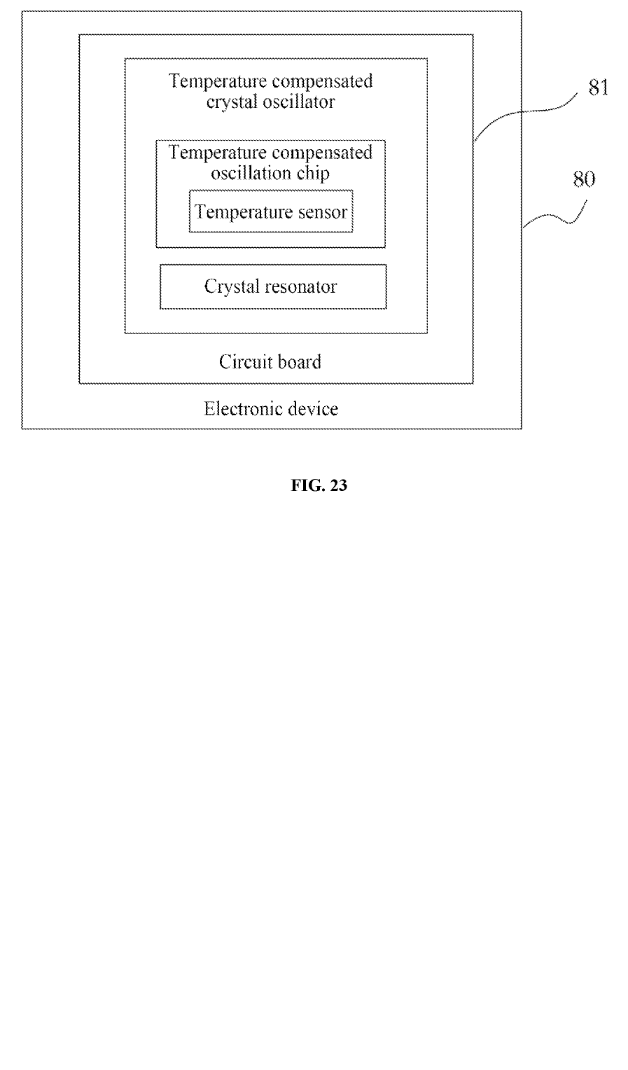

Referring to FIG. 21 and FIG. 22, Embodiment XI provides a flowchart of a manufacturing method of the temperature compensated crystal oscillator shown in FIG. 19, and a structural diagram of steps.

Specifically, the manufacturing method includes the following steps:

Step 591, referring to FIG. 21(A), a substrate 90 is provided, and a first partial insulating layer 43a is formed on the substrate 90.

The substrate 90 is used as a carrier in a manufacturing process, and its material can be selected as needed. Furthermore, the substrate 90 can be removed after the manufacturing of the temperature compensated crystal oscillator main body 62 is completed. It can be understood that a first partial insulating layer 43a can be a part of the insulating layer 43 as shown in FIG. 8 and can be formed by, but is not limited to, a semiconductor deposition process.

Step S92, referring to FIG. 21(B), a plurality of crystal resonators 41 are formed on the first partial insulating layer 43a.

It can be understood that in the above step, the plurality of crystal resonators 41 are spaced apart on the same side surface of the first partial insulating layer 43a, and the plurality of crystal resonators 41 can be formed by the same process. Each crystal resonator 41 can have an electrode structure (such as a second electrode structure 4123) for electrical connection with an external circuit or an oscillation chip.

Step S93, referring to FIG. 21(C), an oscillation chip 42 is arranged on each of the plurality of crystal resonators 41, and on each oscillation chip 42, a plurality of connection ends 42a electrically connected to the oscillation chip 42 are arranged.

It can be understood that the oscillation chip 42 is a temperature compensated oscillation chip, and the connection ends 42a are made of a conductive material and can be formed on one side of the oscillation chip 42 away from the crystal resonator 41 by photolithography (such as a semiconductor deposition etching process). The connection ends 42a include a first connection end 42b and a second connection end 42c.

Step S94, referring to FIG. 21(D), a second partial insulating layer 43b that covers the plurality of crystal resonators 41 and the oscillation chips 42 is formed. The second partial insulating layer 43b and the first partial insulating layer 43a are connected into a whole and can be made of the same material. It can be understood that the second partial insulating layer 43b can be formed by, but is not limited to a semiconductor deposition process.

Step S95, referring to FIG. 21(E), a plurality of second via holes 435 are formed in the second partial insulating layer 43b. The second via holes 435 are configured to expose the second electrode structure 4123. It can be understood that the second via holes 435 can be formed by, but is not limited to, a laser process or a semiconductor deposition etching technology.

Step S96, referring to FIG. 21(F) and FIG. 21(G), a first conductive material is formed on the connection ends 42a, on the second partial insulating layer 43b, and inside the second via holes 435; the second connection ends 42c are electrically connected to the second electrode structure 4123 through the first conductive material on the second partial insulating layer 43b and inside the second via holes 435; and the first connection ends 42b are in contact with and electrically connected to the first conductive material on the first connection ends. The first conductive material can be formed by, but is not limited to a sputtering process or a semiconductor deposition process.

Step S97, referring to FIG. 21(H), a third partial insulating layer 43c is further formed on the second partial insulating layer 43b and the first conductive material.

The third partial insulating layer 43c can be formed by, but is not limited to a semiconductor deposition process. It can be understood that although the first partial insulating layer 43, the second partial insulating layer 43, and the third partial insulating layer 43 are formed in different steps and processes, they jointly form and are equivalent to the insulating layer 43 shown in FIG. 8.

Step S98, referring to FIG. 21(I), a plurality of first via holes 431 are formed on the third partial insulating layer 43c. The plurality of first via holes 431 are configured to expose the first conductive material on the first connection ends 42b.

The first via holes 431 can be formed by, but is not limited to, a laser process or a semiconductor deposition etching technology.

Step S99, referring to FIG. 21(J) and FIG. 21(K), a plurality of first electrode structures 34 are formed on the third partial insulating layer 43c; a second conductive material is formed inside the first via holes 431; and each first electrode structure 34 is electrically connected to the oscillation chips 42 through the second conductive material inside the first via holes 431.

The second conductive material can be formed by, but is not limited to a sputtering process or a semiconductor deposition process and/or an electroplating process.

Step S100, referring to FIG. 21(L), the substrate 90 is removed to obtain a plurality of temperature compensated crystal oscillator main bodies 62 that are connected into a whole.

Step S101, referring to FIG. 21(M), the plurality of temperature compensated crystal oscillator main bodies 62 that are connected into a whole are cut to obtain a plurality of independent temperature compensated crystal oscillator main bodies 62 (which are equivalent to the temperature compensated crystal oscillator 40 shown in FIG. 8).

Step 102, referring to FIG. 21(N), the temperature compensated crystal oscillator main bodies 62 are packaged, so that a protective structure 61 is formed at peripheries of the temperature compensated crystal oscillator main bodies 62. The protective structure 61 is made of an insulating material and is wrapped around the peripheries of the temperature compensated crystal oscillator main bodies 62 (this is basically the same as the structure of the temperature compensated crystal oscillator 40 shown in FIG. 8), and only the electrode structure 63 (equivalent to the first electrode structure 44 shown in FIG. 8) is exposed through a opening region of the protective structure 61. A third conductive material can be further provided on the first electrode structure 44 to cause the first electrode structure 44 to extend out of the protective structure 61.

It can be understood that through step S91 to step S103, the temperature compensated crystal oscillator 40 shown in FIG. 8 and the temperature compensated crystal oscillator main bodies 62 and the temperature compensated crystal oscillator 60 that are shown in FIG. 19 to FIG. 20 can be obtained. Moreover, technical effects of high efficiency, good accuracy and reliability, and significant decrease in size can be achieved by the sputtering process, the semiconductor deposition process, the etching process, or the laser process.

In addition, in step S91 to step S101, the plurality of temperature compensated crystal oscillator main bodies that are connected into a whole can be formed. Then, in step S102, the plurality of temperature compensated crystal oscillator main bodies 62 that are connected into a whole can be cut to obtain the plurality of independent temperature compensated crystal oscillator main bodies 62 (also equivalent to the temperature compensated crystal oscillator 40 shown in FIG. 8). Manufacturing efficiency is high, and batch production reduces production costs.

### Embodiment XII

Referring to FIG. 23, FIG. 23 is a schematic block diagram of an electronic device 80 according to Embodiment XII of the present disclosure. This embodiment further provides an electronic device 80. The electronic device 80 can be, but is not limited to, a portable electronic device such as a mobile phone, a tablet, a display, a laptop, and a digital camera. The electronic device 80 can include a circuit board 81. The temperature compensated crystal oscillator 30, 40,or 50 of any embodiment described above is arranged on the circuit board 81.

The various technical features in the foregoing embodiments may be randomly combined. For concise description, not all possible combinations of the various technical features in the above embodiments are described. However, provided that combinations of these technical features do not conflict with each other, the combinations of the various technical features are considered as falling within the scope of this specification. The foregoing embodiments merely express several implementations of the present invention. The descriptions thereof are relatively specific and detailed, but are not understood as limitations on the scope of the present invention. A person of ordinary skill in the art can also make several transformations and improvements without departing from the idea of this application. These transformations and improvements fall within the protection scope of this application. Therefore, the protection scope of the patent of this application shall be subject to the appended claims.

What is claimed is:

1. An oscillator, comprising:
a resonator, comprising a vibrating element and an airtight packaging structure packaged around the vibrating element;
an oscillation chip, arranged on one side of the airtight packaging structure;
an insulating layer, covering at least one side of the oscillation chip and at least one side of the airtight packaging structure, wherein the insulating layer has a first via hole, and a conductive material is provided in the first via hole; and
a first electrode structure, arranged on the insulating layer and electrically connected to the oscillation chip through the conductive material inside the first via hole.

2. The oscillator according to claim 1, wherein the insulating layer comprises a first portion; the first portion covers one side of the oscillation chip and the airtight packaging structure; the insulating layer further comprises a second portion; the second portion covers one side of the airtight packaging structure away from the oscillation chip; the insulating layer further comprises a third portion; and the third portion is arranged around a peripheral side of the airtight packaging structure and is connected to the first portion and the second portion.

3. The oscillator according to claim 1, wherein the resonator is a ceramic-packaged crystal resonator; the airtight packaging structure comprises a ceramic base body with a cavity, a cover plate covered at the ceramic base body, and a second electrode structure arranged on the ceramic base body; a conductor structure is arranged inside the ceramic base body; the vibrating element is arranged inside the cavity and is connected to the ceramic base body through an adhesive; and the second electrode structure is further electrically connected to the conductor structure and the oscillation chip.

4. The oscillator according to claim 1, wherein the resonator is a crystal resonator packaged in an all-crystal form; the airtight packaging structure comprises a first sealing member arranged on one side of the vibrating element, a second sealing member arranged on another side of the vibrating element, and a second electrode structure arranged on the first sealing member; the first sealing member, the vibrating element, and the second sealing member all comprise crystal materials; the second electrode structure is electrically connected to the oscillation chip; the oscillation chip is arranged on the first sealing member and is electrically connected to the second electrode structure; and the insulating layer covers the oscillation chip and the first sealing member.

5. The oscillator according to claim 1, wherein the resonator is a silicon-based resonator packaged in an all-silicon form; the airtight packaging structure comprises a first sealing member arranged on one side of the vibrating element, a second sealing member arranged on another side of the vibrating element, and a second electrode structure arranged on the first sealing member;
the first sealing member, the vibrating element, and the second sealing member all comprise material silicon; the second electrode structure is electrically connected to the oscillation chip;
the resonator is arranged on a first surface of the oscillation chip; and the insulating layer covers the resonator, the first surface of the oscillation chip, a second surface of the oscillation chip facing away from the first surface, and a side surface connected between the first surface and the second surface.

6. The oscillator according to claim 2, wherein the insulating layer further has a second via hole; a conductive material is provided inside the second via hole; and the second electrode structure is electrically connected to the oscillation chip through the conductive material inside the second via hole.

7. The oscillator according to claim 3, wherein the insulating layer further has a second via hole; a conductive material is provided inside the second via hole; and the second electrode structure is electrically connected to the oscillation chip through the conductive material inside the second via hole.

8. The oscillator according to claim 4, wherein the insulating layer further has a second via hole; a conductive material is provided inside the second via hole; and the second electrode structure is electrically connected to the oscillation chip through the conductive material inside the second via hole.

9. The oscillator according to claim 5, wherein the insulating layer further has a second via hole; a conductive material is provided inside the second via hole; and the second electrode structure is electrically connected to the oscillation chip through the conductive material inside the second via hole.

10. The oscillator according to claim 1, wherein the insulating layer is arranged on at least one side of the oscillation chip and at least one side of the airtight packaging structure through a first semiconductor deposition process; the first via hole is formed in the insulating layer through a semiconductor etching process; the conductive material inside the first via hole is formed in the first via hole through a second semiconductor deposition process; and the first electrode structure is formed in the insulating layer through a third semiconductor deposition process.

11. The oscillator according to claim 1, wherein the resonator is a crystal resonator; the oscillation chip is a temperature compensated oscillation chip with a built-in temperature sensor.

12. A manufacturing method of an oscillator, comprising:
providing an oscillation chip;
providing a resonator, and arranging the resonator on one side of the oscillation chip;
forming an insulating layer with a first via hole on at least one side of the oscillation chip and at least one side of the airtight packaging structure, wherein a conductive material is provided inside the first via hole; and
forming a first electrode structure on the insulating layer, and electrically connecting the first electrode structure to the oscillation chip through the conductive material inside the first via hole.

13. The manufacturing method of the oscillator according to claim 12, wherein the resonator comprises a vibrating element and an airtight packaging structure packaged at a periphery of the vibrating element; the resonator is a ceramic-packaged crystal resonator, an all-crystal-packaged crystal resonator, or an all-silicon-packaged silicon-based resonator; the insulating layer is deposited on the at least one side of the oscillation chip and the at least one side of the airtight packaging structure through a first semiconductor deposition process; the first via hole is formed in the insulating layer through a semiconductor etching process; the conductive material in the first via hole is formed in the first via hole through a second semiconductor deposition process; and the first electrode structure is formed in the insulating layer through a third semiconductor deposition process.

14. The manufacturing method of the oscillator according to claim 12, further comprising a step of providing a substrate, wherein the insulating layer comprises a substrate portion and a covering portion; the step of forming an insulating layer with a first via hole on at least one side of the oscillation chip and at least one side of the airtight packaging structure comprises:
forming the substrate portion on the substrate, and arranging a first surface of the oscillation chip on the substrate portion; and
forming the covering portion on a second surface of the oscillation chip facing away from the first surface, a side surface connected between the first surface and the second surface, and the resonator, and forming the first via hole and the conductive material inside the first via hole in the covering portion,
wherein both the substrate portion and the covering portion are formed through a semiconductor deposition process; and
the manufacturing method of the oscillator further comprises a step of removing the substrate.

15. A manufacturing method of an oscillator, wherein the manufacturing method comprises the following steps:
providing a substrate, and forming a first partial insulating layer on the substrate;
forming a plurality of crystal resonators on the first partial insulating layer;
arranging an oscillation chip on each of the plurality of crystal resonators, and arranging, on each oscillation chip, a plurality of connection ends electrically connected to the oscillation chip, wherein the connection ends comprise a first connection end and a second connection end;
forming a second partial insulating layer that covers the plurality of crystal resonators and the oscillation chips, wherein the second partial insulating layer and the first partial insulating layer are connected into a whole;
forming a plurality of second via holes in the second partial insulating layer, wherein the second via holes are configured to expose a second electrode structure;
forming a first conductive material on the connection ends, on the second partial insulating layer, and inside the second via holes, electrically connecting the second connection ends to the second electrode structure through the first conductive material on the second partial insulating layer and inside the second via holes, and causing the first connection ends to be in contact with and electrically connected to the first conductive material on the first connection ends;
further forming a third partial insulating layer on the second partial insulating layer and the first conductive material;
forming a plurality of first via holes on the third partial insulating layer, wherein the plurality of first via holes are configured to expose the first conductive material on the first connection ends;
forming a plurality of first electrode structures on the third partial insulating layer, forming a second conductive material inside the first via holes, and electrically connecting each first electrode structure to the oscillation chips through the second conductive material inside the first via holes;
removing the substrate to obtain a plurality of temperature compensated crystal oscillator main bodies that are connected into a whole; and
cutting the plurality of temperature compensated crystal oscillator main bodies that are connected into a whole, to obtain a plurality of independent temperature compensated crystal oscillator main bodies.

16. The manufacturing method of the oscillator according to claim 15, wherein the manufacturing method further comprises:
packaging the temperature compensated crystal oscillator main bodies to form a protective structure at peripheries of the temperature compensated crystal oscillator main bodies, wherein the protective structure is made of an insulating material and is wrapped around the peripheries of the temperature compensated crystal oscillator main bodies; and the electrode structures are exposed through an opening region of the protective structure.

17. The manufacturing method of the oscillator according to claim 16, wherein the manufacturing method further comprises:
arranging a third conductive material on the first electrode structures, and causing the first electrode structures to extend out of the protective structure.

18. The manufacturing method of the oscillator according to claim 15, wherein the substrate is used as a carrier in a manufacturing process; the oscillation chips are temperature compensated oscillation chips; and the connection ends are made of conductive materials.

19. The manufacturing method of the oscillator according to claim 15, wherein the third partial insulating layer, the second partial insulating layer, and the first partial insulating layer are connected into a whole, and are all made of the same materials.

20. The manufacturing method of the oscillator according to claim 15, wherein the second via holes are formed by a laser process and/or a semiconductor deposition etching process; the first conductive material is formed by a sputtering or semiconductor deposition process; the first via holes are formed by a laser and/or semiconductor deposition etching process; the second conductive material is formed by sputtering or a semiconductor deposition process; and the second conductive material is formed by a sputtering, semiconductor deposition, and/or electroplating processes.
